(19) United States
(12) Patent Application Publication
(10) Pub. No.: US 2017/0055355 A1
(43) Pub. Date: Feb. 23, 2017

(54) PROTECTIVE CASE

(71) Applicants: Fu Tai Hua Industry (Shenzhen) Co., Ltd., Shenzhen (CN); HON HAI PRECISION INDUSTRY CO., LTD., New Taipei (TW)

(72) Inventors: CHEN-CHING CHU, New Taipei (TW); CHENG-KUO LEE, New Taipei (TW); HUAN-PENG XIN, Shenzhen (CN)

(21) Appl. No.: 14/945,982

(22) Filed: Nov. 19, 2015

(30) Foreign Application Priority Data
Aug. 21, 2015 (CN) 201510517103.X

(51) Int. Cl. H05K 5/02; H01R 31/06; H05K 5/00; H01R 24/58; A45C 11/00; A45F 5/00

(52) U.S. Cl. CPC H05K 5/0247; A45C 11/00; A45F 5/00; H05K 5/0026; H05K 5/0217; H01R 24/58; H01R 31/06

(57) ABSTRACT

A protective case is configured to receive and protect an electronic device with an audio interface. The protective case includes an audio jack aligning with the audio interface of the electronic device, an earphone connected to an earphone wire, a circuit board, a plurality of contacts set in the audio jack and connected to the earphone wire via the circuit board, and an audio connector. The audio connector includes a base and a connection-peg. The base includes a plurality of metal contacts, and each metal contact corresponds to one contact. The connection-peg is electrically connected to the plurality of metal contacts. When the connection-peg is inserted into the audio interface of the electronic device via the audio jack, the plurality of the contacts are correspondingly and electrically connected to the plurality of the metal contacts, and the electronic device is electrically connected to the earphone.

### CROSS-REFERENCE TO RELATED APPLICATIONS

This application claims priority to Chinese Patent Application No. 201510517103.X filed on Aug. 21, 2015, the contents of which are incorporated by reference herein.

### FIELD

The subject matter herein generally relates to protective cases, especially relates to a protective case for protecting portable electronic devices.

### BACKGROUND

Protective cases for portable electronic devices currently on the market include an audio connector and a built-in headset. The protective case usually connects to the audio connector and the built-in headset via a metal wire. When a user of the electronic device needs to use the built-in headset, the audio connector must be inserted into the audio jack of the electronic device. When the external headset or audio equipment of the electronic device is needed, the audio connector must be pulled out from the audio jack.

### BRIEF DESCRIPTION OF THE DRAWINGS

Implementations of the present technology will now be described, by way of example only, with reference to the attached figures.

FIG. 1 is an isometric view illustrating an embodiment of a protective case and an electronic device.

FIG. 2 is a first exploded, isometric view of the protective case shown in FIG. 1.

FIG. 3 is a second exploded, isometric view of the protective case shown in FIG. 1.

FIG. 4 is a first perspective view showing the protective case of FIG. 1 together with an electronic device.

FIG. 5 is a second perspective view showing the protective case of FIG. 1 together with an electronic device.

FIG. 6 is a sectional view of the protective case taken along line VI-VI of FIG. 5.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The term “comprising” means “including, but not necessarily limited to”; it specifically indicates open-ended inclusion or membership in a so-described combination, group, series and the like.

Embodiments of the present disclosure will be described in relation to the accompanying drawings.

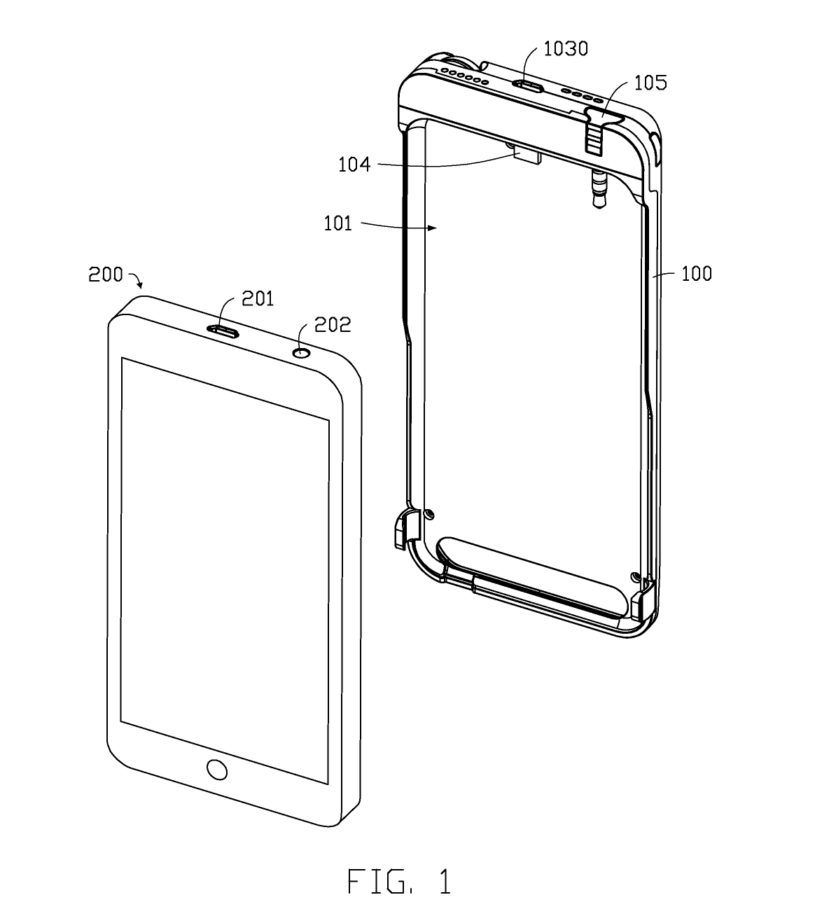

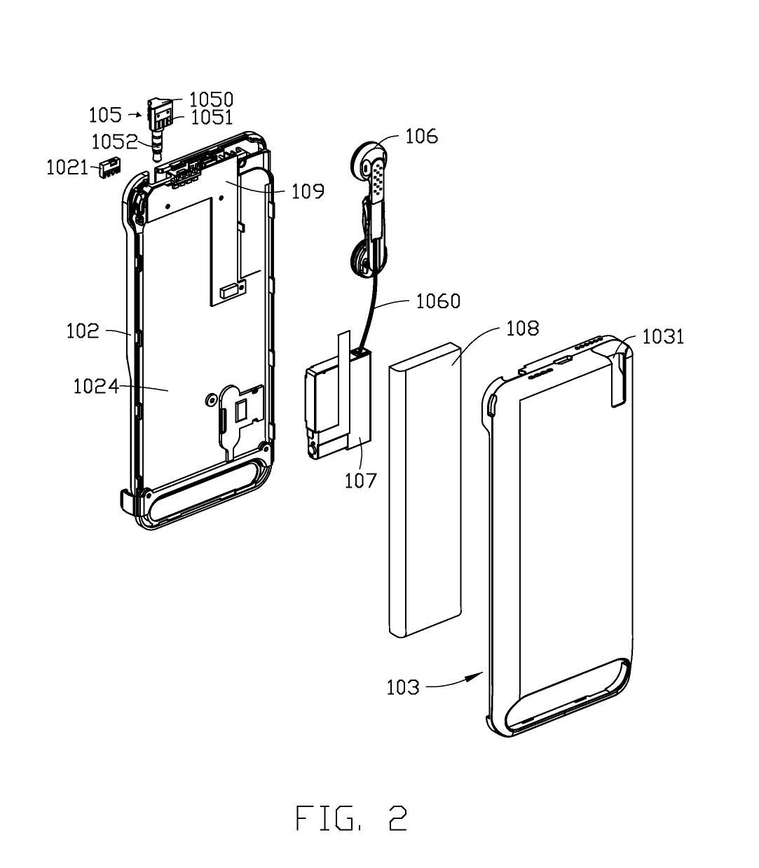

FIG. 1 illustrates an isometric view showing an embodiment of a protective case 100 and an electronic device 200. The protective case 100 is used to receive and protect the electronic device 200. In at least one embodiment, the electronic device 200 includes a data interface 201 and an audio interface 202. The protective case 100 includes a receiving space 101 to receive the electronic device 200, a data connector 104, a data jack 1030, an audio connector 105, and an audio jack 1020 (as shown in FIG. 2). When the electronic device 200 is received in the receiving space 101, the data connector 104 and the data jack 1030 align with the data interface 201 of the electronic device 200, and the audio connector 105 and the audio jack 1020 align with the audio interface 202 of the electronic device 200.

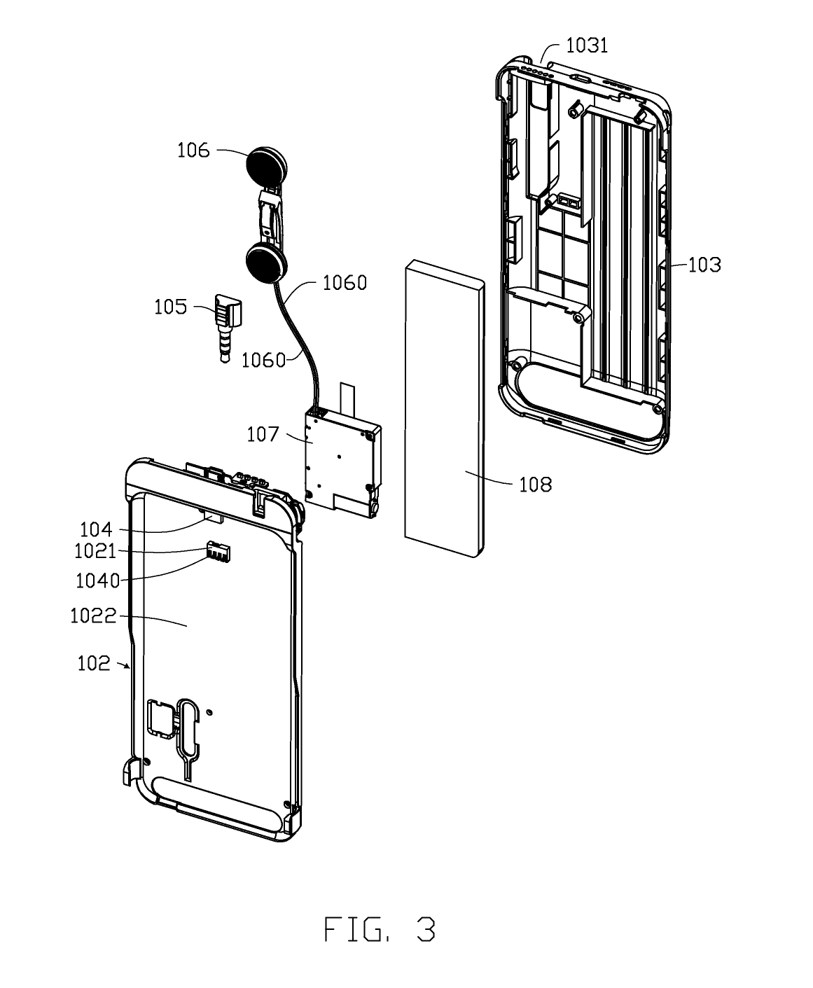

FIG. 2 and FIG. 3 illustrate exploded, isometric views of the protective case 100 shown in FIG. 1. In at least one embodiment, the protective case 100 includes a first backplane 102 and a second backplane 103. The receiving space 101 is set on a first side 1022 of the first backplane 102. A circuit board 109 is set on a second side 1024 of the first backplane 102. The audio connector 105 is inserted in the audio jack 1020. A spring seat 1021 is set in the audio jack 1020. The spring seat 1021 includes a number of contacts 1040. Each of the contacts 1040 is electrically connected to the circuit board 109. In at least one embodiment, the circuit board 109 includes at least one circuit (not shown), the contacts 1040 electrically connect to the at least one circuit to accomplish the electrical connection between the number of contacts 1040 and the circuit board 109. In at least one embodiment, the contact 1040 can be a metal dome.

The audio connector 105 includes a base 1050 and a connection-peg 1052. In at least one embodiment, the connection-peg 1052 can be a three section connector or a four section connector of existing technology. A number of metal contacts 1051 are set on the base 1050. Each metal contact 1051 corresponds to one of the contacts 1040 of spring seat 1021 and one section of the connection-peg 1052. Each metal contact 1051 is electrically connected to one section of the connection-peg 1052 corresponding to the metal contact 1051. In at least one embodiment, the connection-peg 1052 includes four sections, the number of the contacts 1040 of the spring seat 1021 and the number of the metal contacts 1051 are both four. When the audio connector 105 is inserted into the audio jack 1020, the four metal contacts 1051 of audio connector 105 are electrically and correspondingly connected to the four contacts 1040 of the spring seat 1021, so that the connection-peg 1052 is electrically connected to the circuit board 109.

The protective case 100 further includes a reel 107 and a battery 108. The reel 107 and the battery 108 are both set on the second side 1024 of the first backplane 102. The reel 107 and the battery 108 are both electrically connected to the circuit board 109. Both of the data connector 104 and the data jack 1030 are electrically connected to the circuit board 109. When the electronic device 200 is received in the receiving space 101 of the protective case 100, the data connector 104 of the protective case 100 is inserted into the data interface 201 of the electronic device 200, the electronic device 200 is charged by the battery 108 via the circuit board 109, and users can exchange data with the electronic device 200 via the data jack 1030 of the protective case 100. Meanwhile, the battery 108 can supply electricity for the reel 107.

The protective case 100 further includes a built-in earphone 106. The second board 103 of the protective case 100 defines a receiving hole 1031 to receive the earphone 106.

The earphone 106 connects with an earphone wire 1060. The reel 107 set on the second side 1024 of the first board 102 is used to entwine the earphone wire 1060. A number of signal lines (not shown) of the earphone wire 1060 are electrically and correspondingly connected to the number of the contacts 1040 of the spring seat 1040 via the circuit board 109.

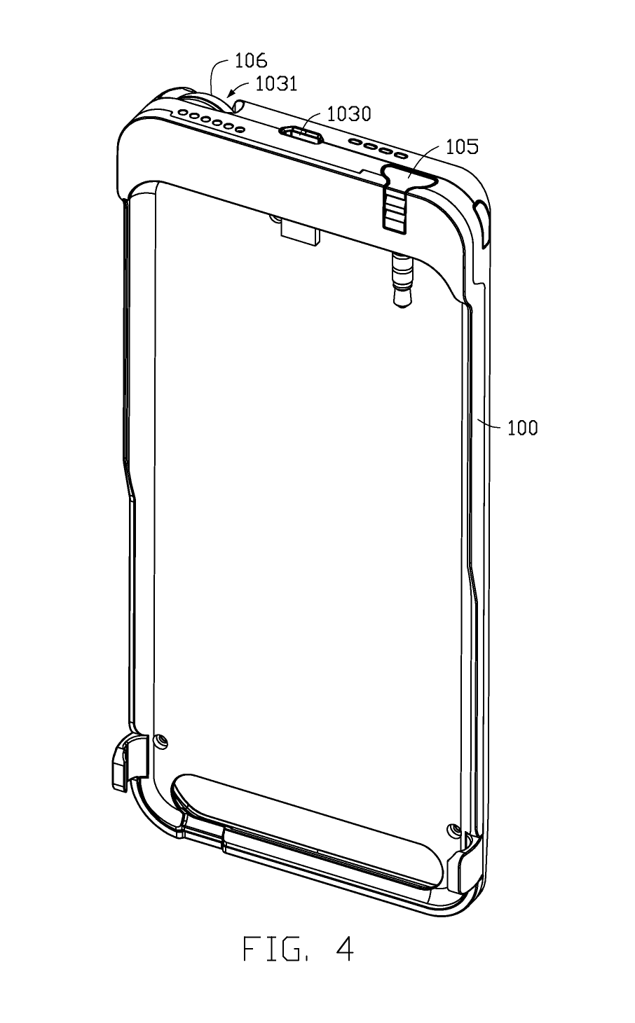

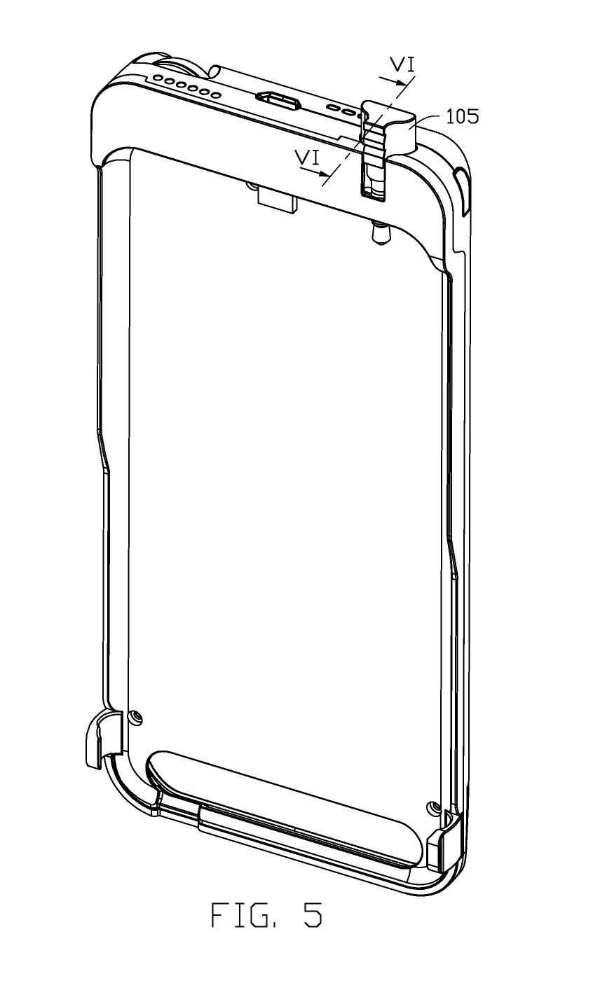

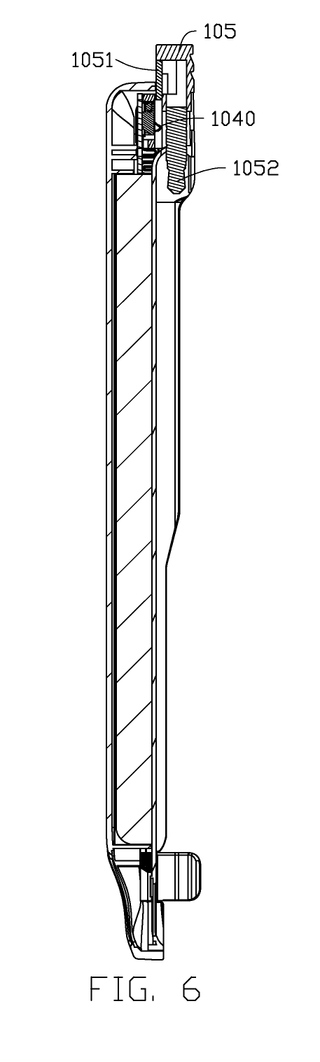

FIG. 4 and FIG. 5 illustrate perspective views showing the protective case 100 installed around the electronic device. When the electronic device 200 is received in the receiving space 101 of the protective case 100, the data connector 104 is inserted into the data interface 201 of the electronic device 200, and the audio connector 105 is inserted into the audio interface 202 of the electronic device 200 through the audio jack 1020. The earphone 106 of the protective case 100 as illustrated in FIG. 6 can be electrically connected to the audio interface 202 of the electronic device 200 via the earphone wire 1060, the circuit board 109, the contacts 1040, the metal contact 1051, and the connection-peg 1052, thus audio signals of the electronic device 200 can be sent to the earphone 106 of the protective case 100.

When the audio connector 105 is partially pulled out from the audio jack 1020, the metal contacts 1051 are separated from the contacts 1040, and the earphone 106 is disconnected from the electronic device 200. When the earphone 106 is disconnected from the electronic device 200, an audio output device of the electronic device 200, such as a speaker or a receiver is turned on. In at least one embodiment, a clamping mechanism can further be set between the audio connector 105 and the audio jack 1020 to protect the audio connector 105 from being separated from the audio jack 1020. When the audio connector 105 is partially pulled out from the audio jack 1020, the audio connector 105 can be clamped in the audio jack 1020 by the clamping mechanism.

When the audio connector 105 is completely pulled out from the audio jack 1020, the user can insert other audio devices, such as an external earphone, into the audio interface 202 of the electronic device 200 through the audio jack 1020.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A protective case configured to receive and protect an electronic device with an audio interface and a data interface, the protective case comprising:
an audio jack configured to align with the audio interface of the electronic device;
an earphone configured to connect to an earphone wire;
a circuit board configured to be coupled in the audio jack and the earphone;
a plurality of contacts set in the audio jack and configured to connect to the earphone wire via the circuit board;
an audio connector comprising:
a base comprising a plurality of metal contacts, wherein, each metal contact corresponds to one contact; and
a connection-peg configured to be inserted into the audio interface of the electronic device and electrically connected to the plurality of metal contacts.

2. The protective case according to claim 1, wherein the protective case further comprises a battery and a data connector configured to align with the data interface of the electronic device, the battery and the data connector are electrically connected to the circuit board.

3. The protective case according to claim 2, wherein the data connector is configured to insert into the data interface of the electronic device and the battery is configured to charge for the electronic device via the circuit board.

4. The protective case according to claim 2, wherein the protective case further comprises a reel configured to entwine the earphone wire of the earphone, the reel is electrically connected to the circuit board and the battery supplies electricity for the reel.

5. The protective case according to claim 2, wherein the protective case further comprises a data jack, the data jack is configured to exchange data with the electronic device.

6. The protective case according to claim 1, wherein the plurality of the contacts are set on a spring seat which is set in the audio jack.

7. The protective case according to claim 1, wherein the connection-peg is a four section connector, the number of the contacts and the number of the metal contacts are both four.
